(19) United States
(12) Patent Application Publication
(10) Pub. No.: US 2024/0215418 A1
(43) Pub. Date: Jun. 27, 2024

(54) OLED DISPLAY PANEL

(71) Applicants: WUHAN CHINA STAR OPTOELECTRONICS TECHNOLOGY CO., LTD., Wuhan (CN); WUHAN CHINA STAR OPTOELECTRONICS SEMICONDUCTOR DISPLAY TECHNOLOGY CO., LTD., Wuhan (CN)

(72) Inventor: Hongmei LIU, Wuhan (CN)

(21) Appl. No.: 17/296,339

(22) PCT Filed: May 12, 2021
(86) PCT No.: PCT/CN2021/093365

§ 371 Date: Jan. 18, 2024

(30) Foreign Application Priority Data
Apr. 26, 2021 (CN) 202110451288.4

(51) Int. Cl. H10K 59/80; H10K 59/124

(52) U.S. Cl. CPC H10K 59/8794; H10K 59/124; H10K 59/8792

(57) ABSTRACT

The present application discloses an OLED display panel. The OLED display panel includes at least one thermal conduction functional layer. A preparation material of the thermal conduction functional layer is a transparent graphite material. By disposing the thermal conduction functional layer in the OLED display panel, in-plane temperature uniformity is improved.

### CROSS REFERENCE TO RELATED APPLICATIONS

This application is a National Phase of PCT Patent Application No. PCT/CN2021/093365 having International filing date of May 12, 2021, which claims the benefit of priority of Chinese Patent Application No. 202110451288.4, filed Apr. 26, 2021, the contents of which are all incorporated herein by reference in their entirety.

### FIELD OF INVENTION

The present disclosure relates to the field of organic light emitting diode (OLED) display technology, in particular to an OLED display panel.

### DESCRIPTION OF PRIOR ART

In order to eliminate adverse effects of a polarizer, existing OLED display panels usually adopt OLED display panels with a pol-less structure to replace the polarizer. The OLED display panels with the pol-less structure are mainly composed of color resist blocks and black matrices. The color resist blocks can control incident light entering light-emitting units and make reflected lights thereof become lights of a same color as the light-emitting units, which eliminates reflection of ambient lights on a reflective surface. The black matrices can block external ambient incident light entering other portions except the light-emitting units, and therefore reflected lights of other metal wires are suppressed.

During operation of the OLED display panels, due to problems such as current uniformity and in-plane resistance uniformity, heat emitting conditions at different positions are different. Uneven in-plane temperatures will result in poorer brightness uniformity of OLED light emission, causing a series of problems such as uneven in-plane brightness and uneven chromaticity.

Therefore, the existing OLED display panels have a technical problem of the uneven in-plane temperatures.

### SUMMARY OF INVENTION

### Technical Problem

Embodiments of the present disclosure provides an OLED display panel, which can alleviate a technical problem of uneven in-plane temperatures of an existing OLED display panel.

### Technical Solution

To solve the above problems, the present disclosure provides technical solutions as follows:

The present disclosure provides an OLED display panel, comprising a substrate, light-emitting units, a pixel definition layer, and an encapsulation layer, wherein the OLED display panel further comprises at least one thermal conduction functional layer, and a preparation material of the thermal conduction functional layer is a transparent graphite material.

Alternatively, in some embodiments of the present disclosure, the preparation material of the thermal conduction functional layer is graphene.

Alternatively, in some embodiments of the present disclosure, the graphene has a multilayer structure.

Alternatively, in some embodiments of the present disclosure, the OLED display panel further comprises a color filter disposed on the encapsulation layer, and the color filter comprises black matrices and color resist blocks arranged at intervals, and a preparation material of the black matrices is graphite.

Alternatively, in some embodiments of the present disclosure, the OLED display panel further comprises an interlayer insulating layer and a planarization layer, and the thermal conduction functional layer is disposed between the interlayer insulating layer and the planarization layer.

Alternatively, in some embodiments of the present disclosure, the thermal conduction functional layer is disposed on an entire surface between the interlayer insulating layer and the planarization layer.

Alternatively, in some embodiments of the present disclosure, a recessed area is disposed on an upper surface of the interlayer insulating layer, and the thermal conduction functional layer is disposed in the recessed area.

Alternatively, in some embodiments of the present disclosure, a cross-sectional shape of the recessed area is any one of a rectangle, a trapezoid, a triangle, a rhombus, or a parallelogram.

Alternatively, in some embodiments of the present disclosure, the thermal conduction functional layer is disposed between the black matrices and the encapsulation layer.

Alternatively, in some embodiments of the present disclosure, an orthographic projection of the thermal conduction functional layer on the substrate coincides or overlaps an orthographic projection of the black matrices on the substrate.

Alternatively, in some embodiments of the present disclosure, the thermal conduction functional layer is disposed between the color resist blocks and the encapsulation layer.

Alternatively, in some embodiments of the present disclosure, the color filter further comprises a cover plate disposed above the black matrices, and the thermal conduction functional layer is disposed between the cover plate and the black matrices/the color resist blocks.

Alternatively, in some embodiments of the present disclosure, the thermal conduction functional layer is disposed on both upper surfaces and lower surfaces of the black matrices/color resist blocks.

Alternatively, in some embodiments of the present disclosure, the cover plate is disposed above the black matrices, and an optical adhesive is disposed on a surface of the black matrices facing the cover plate.

Alternatively, in some embodiments of the present disclosure, the black matrices are provided with grooves, and the optical adhesive is partially filled in the grooves.

Alternatively, in some embodiments of the present disclosure, the thermal conduction functional layer is an insulating material, and the thermal conduction functional layer can be disposed between any adjacent film layers.

Alternatively, in some embodiments of the present disclosure, the thermal conduction functional layer is a conductive material, and the thermal conduction functional layer is disposed between any adjacent insulating layers.

Alternatively, in some embodiments of the present disclosure, the OLED display panel further comprises an isolation layer, the isolation layer is an insulating material, and the isolation layer is disposed on at least one surface of the thermal conduction functional layer.

Alternatively, in some embodiments of the present disclosure, the isolation layer is disposed around the thermal conduction functional layer.

Alternatively, in some embodiments of the present disclosure, the thermal conduction functional layer is one or more of a buffer layer, an interlayer insulating layer, a planarization layer, or the encapsulation layer.

The OLED display panel provided by the embodiments of the present disclosure comprises the substrate, the light-emitting units, the pixel definition layer, and the encapsulation layer. Wherein the OLED display panel further comprises at least one thermal conduction functional layer. The preparation material of the thermal conduction functional layer is the transparent graphite material. By setting the thermal conduction functional layer in the OLED display panel, the thermal conduction functional layer has an effect of increasing uniformity of in-plane temperature, thereby alleviating the technical problem of the uneven in-plane temperatures of the existing OLED display panel.

### Advantageous Effect

The present disclosure changes the design of the second data line in the data lines located between the display pixel unit and the dummy pixel unit, and the projection of the second data line and the projection of the main electrode of the adjacent dummy pixel electrode are partially overlapped to form the overlap area, so that a capacitance is formed between the second data line and other film layers of the dummy pixel unit, thereby increasing the capacitive load on the second data line, and reducing the charging rate of the display pixel unit corresponding to the second data line, which ensures that the charging rate of each display pixel unit in the array substrate is equivalent, and therefore the poor display effect at the edge of the display panel with the array substrate is improved.

### DESCRIPTION OF DRAWINGS

In order to more clearly explain the technical solutions in the embodiments of the present disclosure, the following will briefly introduce the drawings required in the description of the embodiments. Obviously, the drawings in the following description are only some embodiments of the present disclosure. For those skilled in the art, without paying any creative work, other drawings can be obtained based on these drawings.

FIG. 1 is a first schematic cross-sectional view of an OLED display panel provided by an embodiment of the present disclosure.

FIG. 2 is a second schematic cross-sectional view of an OLED display panel provided by an embodiment of the present disclosure.

FIG. 3 is a third schematic cross-sectional view of an OLED display panel provided by an embodiment of the present disclosure.

FIG. 4 is a fourth schematic cross-sectional view of an OLED display panel provided by an embodiment of the present disclosure.

FIG. 5 is a fifth schematic cross-sectional view of an OLED display panel provided by an embodiment of the present disclosure.

FIG. 6 is a sixth schematic cross-sectional view of an OLED display panel provided by an embodiment of the present disclosure.

### DESCRIPTION OF REFERENCE SIGNS

| Reference | | Reference | |
|---|---|---|---|
| sign | Element name | sign | Element name |
| 1 | OLED display panel | 60 | Color filter |
| 10 | Substrate | 601 | Black matrix |
| 20 | Light-emitting unit | 602 | Color resist block |
| 30 | Pixel definition layer | 603 | Cover plate |
| 40 | Encapsulation layer | 70 | Optical adhesive |
| 50 | Thermal conduction | 80 | Groove |
| | functional layer | | |

### INVENTION EMBODIMENTS

### Detailed Description of Embodiments

Technical solutions in embodiments of the present disclosure will be clearly and completely described below in conjunction with drawings in the embodiments of the present disclosure. Obviously, the described embodiments are only a part of embodiments of the present disclosure, rather than all the embodiments. Based on the embodiments in the present disclosure, all other embodiments obtained by those skilled in the art without creative work fall within the protection scope of the present disclosure. In addition, it should be understood that the specific implementations described here are only used to illustrate and explain the present disclosure, and are not used to limit the present disclosure. In the present disclosure, unless otherwise stated, directional words used such as “upper” and “lower” generally refer to the upper and lower directions of the device in actual use or working state, and specifically refer to the drawing directions in the drawings; and “inner” and “outer” refer to the outline of the device.

An embodiment of the present disclosure provides an OLED display panel. Detailed descriptions are given below. It should be noted that an order of description of the following embodiments is not meant to limit a preferred order of the embodiments.

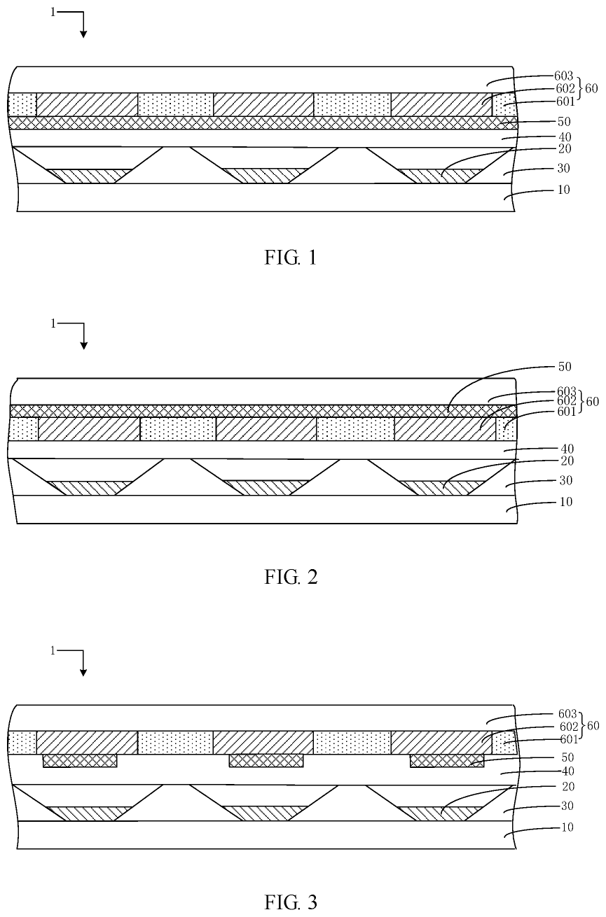

As shown in FIG. 1, an OLED display panel 1 provided by an embodiment of the present disclosure comprises a substrate 10, light-emitting units 20, a pixel definition layer 30, and an encapsulation layer 40. Wherein, the OLED display panel 1 further comprises at least one thermal conduction functional layer 50. A preparation material of the thermal conduction functional layer 50 is a transparent graphite material.

Wherein, the transparent graphite material has characteristics of light transmittance and high thermal conductivity, and a heat dissipation capacity of the thermal conduction functional layer 50 is greater than a heat dissipation capacity of other film layers of the OLED display panel 1.

Wherein, the OLED display panel 1 may further comprise a color filter 60 disposed on the encapsulation layer 40, and the color filter 60 comprises black matrices 601, color resist blocks 602, and a cover plate 603.

In the present embodiment, the OLED display panel 1 comprises the substrate 10, the light-emitting units 20, the pixel definition layer 30, and the encapsulation layer 40. Wherein, the OLED display panel 1 further comprises at least one thermal conduction functional layer 50, and the preparation material of the thermal conduction functional layer 50 is the transparent graphite material. By setting the thermal conduction functional layer 50 in the OLED display panel 1, the thermal conduction functional layer 50 has an effect of increasing in-plane temperature uniformity and accelerating heat dissipation of the panel, thereby improving uniformity of brightness and chromaticity of the OLED display panel 1 and alleviating a technical problem of uneven in-plane temperatures of an existing OLED display panel 1.

In an embodiment, preparation materials of the thermal conduction functional layer 50 comprise, but are not limited to, the transparent graphite material.

Wherein, the preparation materials of the thermal conduction functional layer 50 may be materials with electrical and thermal conductivity.

Wherein, the preparation materials of the thermal conduction functional layer 50 may also be insulating materials.

In the present embodiment, when the preparation material of the thermal conduction functional layer 50 has electrical conductivity, the thermal conduction functional layer 50 can only be disposed between adjacent insulating film layers and insulated from other conductive film layers, which prevents conduction between the thermal conduction functional layer 50 and other conductive film layers in the OLED display panel 1, which would cause abnormal display.

In an embodiment, the thermal conduction functional layer 50 is made of the insulating materials.

Wherein, the thermal conduction functional layer 50 can be disposed in any region of the OLED display panel 1 or between adjacent film layers.

Wherein, the thermal conduction functional layer 50 can be an existing film layer in the OLED display panel 1, for example the thermal conduction functional layer 50 may be one or more layers of a buffer layer, an interlayer insulating layer, a planarization layer, and the encapsulation layer 40.

In the present embodiment, when the thermal conduction functional layer 50 is a newly-added film layer in the OLED display panel 1, since the thermal conduction functional layer 50 is made of the insulating materials, the thermal conduction functional layer 50 can be directly disposed between any adjacent film layers, and thus an arrangement scheme and preparation process are relatively simple, and there is no need to add other insulating material layers to insulate the thermal conduction functional layer 50 from other conductive layers, which reduces cost.

In the present embodiment, when the thermal conduction functional layer 50 is an existing film layer of the OLED, since there is no need to add a film layer to the OLED display panel 1 as the thermal conduction functional layer 50, a thickness of the film layers in the OLED display panel 1 is reduced or needs not be increased. With excellent thermal conductivity of the transparent graphite material, in-plane heat dissipation of the OLED display panel 1 is increased and the in-plane temperature uniformity is achieved, while a technical effect of the OLED display panel 1 being lighter and thinner is also achieved.

In an embodiment, the preparation material of the thermal conduction functional layer 50 is graphene.

Wherein, at room temperature, thermal conductivity of the graphene ranges from 500 W/m·K to 600 W/m·K. At the same time, since a thickness of the graphene is very thin, it has a relatively good permeability.

Wherein, the graphene may have a structure of a single layer or multiple layers, which is selected according to actual thermal conduction requirements and overall thickness requirements of the OLED display panel 1.

In the present embodiment, good thermal conductivity and light transmittance properties of the graphene are utilized, and the thermal conduction functional layer 50 is made of the graphene, which improves the uniformity of brightness and chromaticity of the OLED display panel 1.

In an embodiment, the OLED display panel 1 further comprises the color filter 60 disposed on the encapsulation layer 40, and the color filter 60 comprises the black matrices 601 and the color resist blocks 602 disposed at intervals. A preparation material of the black matrices 601 is graphite.

Wherein, the color resist blocks 602 are used to process reflected lights of ambient incident light entering the light-emitting units 20 and make the reflected lights become lights of a same color as the light-emitting units 20, which eliminates reflection of the ambient lights on a reflective surface. Meanwhile, the black matrices 601 can block external ambient incident light entering other portions except the light-emitting units 20, reduce reflection of the external ambient lights, eliminate color shift of emitted lights, and reduce power consumption.

Wherein, the preparation material of the black matrices 601 is graphite, graphite has excellent thermal conductivity and opacity, and a thermal conductivity index of the graphite decreases with increasing temperature. At room temperature, the thermal conductivity of the graphite is excellent and better than that of metal materials such as steel, iron, and lead.

In the present embodiment, the material of the black matrices 601 of the color filter 60 is set to graphite, with high thermal conductivity and shading properties of the graphite, the reflection of the external ambient lights is reduced, the color shift of the emitted lights is eliminated, and the power consumption is decreased.

In an embodiment, the OLED display panel 1 further comprises the interlayer insulating layer and the planarization layer, and the thermal conduction functional layer 50 is disposed between the interlayer insulating layer and the planarization layer.

Wherein, the thermal conduction functional layer 50 may be disposed on an entire surface between the interlayer insulating layer and the planarization layer.

Wherein, the thermal conduction functional layer 50 may also be disposed in part of regions of the OLED display panel 1, for example, a recessed area is disposed on an upper surface of the interlayer insulating layer, and the thermal conduction functional layer 50 is disposed in the recessed area.

In the present embodiment, by setting the thermal conduction functional layer 50 in only in part of the regions of the OLED display panel 1, a thickness of the film layers of the OLED display panel 1 in the present embodiment may not be increased, and at the same time the in-plane heat dissipation rate is increased.

In an embodiment, as shown in FIG. 2, the thermal conduction functional layer 50 is disposed between the black matrices 601 and the encapsulation layer 40.

Wherein, an orthographic projection of the thermal conduction functional layer 50 on the substrate 10 coincides or overlaps an orthographic projection of the black matrices 601 on the substrate 10.

In the present embodiment, by setting the thermal conduction functional layer 50 under the black matrices 601, the light transmittance of the OLED display panel 1 will not be affected. At the same time, the materials of the thermal conduction functional layer 50 can also be selected from transmissive materials, which increases a material selection range of the thermal conduction functional layer 50 and reduces the cost.

In an embodiment, the preparation material of the thermal conduction functional layer 50 may be a viscous material, which also has an effect of increasing viscosity between the black matrices 601 and the encapsulation layer 40.

In the present embodiment, the thermal conduction functional layer 50 also has an effect of increasing bonding force between adjacent film layers in the OLED display panel.

In an embodiment, as shown in FIG. 3, the thermal conduction functional layer 50 is disposed between the color resist blocks 602 and the encapsulation layer 40.

Wherein, the preparation material of the thermal conduction functional layer 50 is a light transmissive material.

Wherein, the preparation material of the thermal conduction functional layer 50 may be graphene.

In an embodiment, the color filter 60 further comprises the cover plate 603 disposed above the black matrices 601, and the thermal conduction functional layer 50 is disposed between the cover plate 603 and the black matrices 601/the color resist blocks 602.

Wherein, the thermal conduction functional layer 50 is correspondingly disposed between the cover plate 603 and the black matrices 601, the orthographic projection of the black matrices 601 on the substrate 10 coincides or overlaps the orthographic projection of the thermal conduction functional layer 50 on the substrate 10, which increases the heat dissipation effect and does not affect the light transmittance of the OLED display panel 1.

Wherein, when the preparation material of the black matrices 601 is graphite, since the bonding force between the graphite and the cover plate 603 is relative weak, the preparation material of the thermal conduction functional layer 50 may be the viscous material. The thermal conduction functional layer 50 has excellent thermal conductivity property and can also increase the bonding force between the black matrices 601 and the cover plate 603, which alleviates a technical problem that the black matrices 601 and the cover plate 603 are prone to peeling.

In an embodiment, as shown in FIG. 4, both upper surfaces and lower surfaces of the black matrices 601/the color resist blocks 602 are defined with the thermal conduction functional layer 50.

Wherein, both the upper surfaces and the lower surfaces of the black matrices 601 and the color resist blocks 602 are defined with the thermal conduction functional layer 50.

Wherein, both the upper surfaces and the lower surfaces of the black matrices 601 or the color resist blocks 602 are defined with the thermal conduction functional layer 50.

In the present embodiment, by providing multiple layers of the thermal conduction functional layer 50, the in-plane temperature heat dissipation efficiency is further increased, and the in-plane temperature uniformity is adjusted.

In an embodiment, the preparation material of the black matrices 601 may be graphite, and the preparation material of the black matrices 601 is not limited to graphite, and may also be other materials having same characteristics as graphite.

In an embodiment, the preparation material of the thermal conduction functional layer 50 may be graphene or a transparent graphite material, and the preparation material of the thermal conduction functional layer 50 is not limited to the graphene or the transparent graphite material, and may also be other materials with same characteristics as graphene.

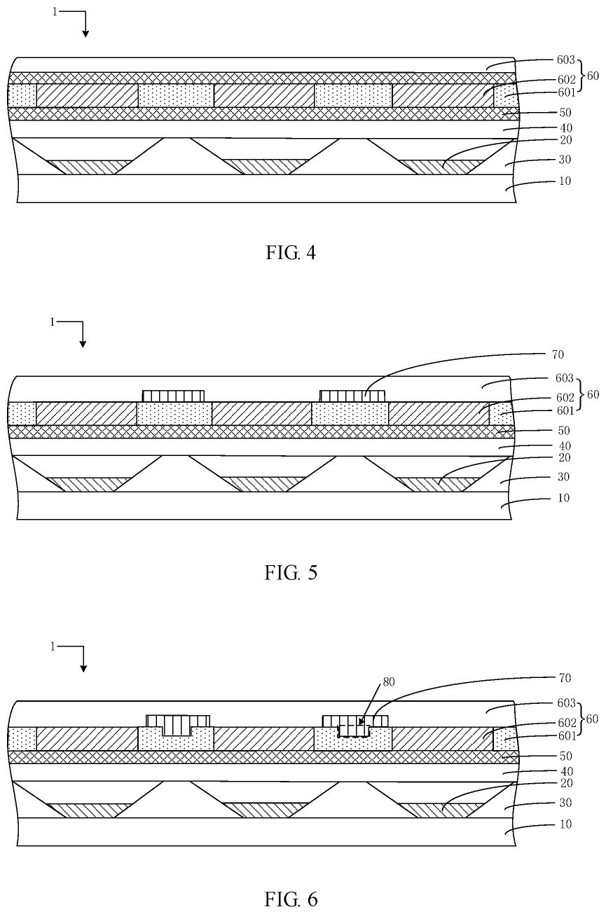

In an embodiment, as shown in FIG. 5, the cover plate 603 is disposed above the black matrix 601, and an optical adhesive 70 is disposed on a surface of the black matrices 601 facing the cover plate 603.

Wherein, the preparation material of the black matrices 601 may be graphite. Since the bonding force between the graphite and a preparation material of the cover plate 603 is weak, the optical adhesive 70 may be disposed on the surface of the black matrices 601 facing the cover plate 603. The bonding force of the black matrices 601 and the cover plate 603 is enhanced through the optical adhesive 70.

In the present embodiment, the optical adhesive 70 is disposed to alleviate a technical problem of the bonding force reduction between film layers caused by the black matrices 601 being set to the graphite, to increase the bonding force between the cover plate 603 and the black matrices 601, and to alleviate a film peeling phenomenon between the black matrices 601 and the cover plate 603 in the color filter 60.

In an embodiment, as shown in FIG. 6, the black matrices 601 are provided with grooves 80, and the optical adhesive 70 is partially filled in the grooves 80.

Wherein, a cross-sectional shape of the grooves 80 may be any one of a rectangle, a triangle, or a trapezoid.

Wherein, a plurality of grooves 80 may be disposed in the black matrices 601, and distance between adjacent grooves 80 may be equal.

Wherein, the grooves 80 may be arranged in an array on the black matrices 601.

In the present embodiment, by defining the grooves 80 on the black matrices 601, the grooves 80 are filled with the optical adhesive 70. By defining the grooves 80 on the black matrices 601, a contact area between the optical adhesive 70 and the black matrices 601 is increased, and the bonding force between the cover plate 603 and the black matrices 601 is increased through adhesion of the optical adhesive 70.

In an embodiment, the OLED display panel 1 comprises the color filter 60, and the color filter 60 is attached to a surface of the encapsulation layer 40 away from the substrate 10, and the color filter 60 comprises the black matrices 601, the color resist blocks 602, and the cover plate 603. The optical adhesive 70 is disposed on a side of the black matrices 601 close to the encapsulation layer 40.

Wherein, the cross-sectional shape of the grooves 80 may be any one of a rectangle, a triangle, or a trapezoid.

Wherein, the plurality of grooves 80 may be disposed on a surface of the black matrices 601 close to the encapsulation layer 40, and the distance between adjacent grooves 80 may be equal.

Wherein, the grooves 80 may be arranged in array on the surface of the black matrices 601 close to the encapsulation layer 40.

In the present embodiment, by defining the grooves 80 on the surface of the black matrix 601 close to the encapsulation layer 40, the grooves 80 are filled with the optical adhesive 70, and by defining the grooves 80 in the black matrices 601, the contact area between the optical adhesive 70 and the black matrices 601 is increased, the bonding force between the color filter 60 and the encapsulation layer 40 is increased by the adhesion of the optical adhesive 70.

In summary, the OLED display panel provided by the embodiments of the present disclosure comprises the substrate, the light-emitting units, the pixel definition layer, and the encapsulation layer. Wherein, the OLED display panel further comprises at least one thermal conduction functional layer, and the preparation material of the thermal conduction functional layer is transparent graphite material. By setting the thermal conduction functional layer in the OLED display panel, the thermal conduction functional layer has an effect of increasing the in-plane temperature uniformity and accelerating the heat dissipation of the panel, thereby improving the uniformity of brightness and chromaticity of the OLED display panel and alleviating the technical problem of the uneven in-plane temperatures of the existing OLED display panel.

The above provides a detailed introduction to the OLED display panel provided by the embodiments of the present disclosure. Specific examples are used to illustrate principles and implementations of the present disclosure. The description of the above embodiments is only used to help understand the methods and the core ideas of the present disclosure. At the same time, for those skilled in the art, according to the idea of the present disclosure, there will be changes in the specific implementation and the scope of application. In summary, the content of this specification should not be construed as a limitation to the present disclosure.

1. An organic light emitting diode (OLED) display panel, comprising a substrate, light-emitting units, a pixel definition layer, and an encapsulation layer, wherein the OLED display panel further comprises at least one thermal conduction functional layer, and a preparation material of the thermal conduction functional layer is a transparent graphite material.

2. The OLED display panel of claim 1, wherein the preparation material of the thermal conduction functional layer is graphene.

3. The OLED display panel of claim 2, wherein the graphene has a multilayer structure.

4. The OLED display panel of claim 1, wherein the OLED display panel further comprises a color filter disposed on the encapsulation layer, and the color filter comprises black matrices and color resist blocks arranged at intervals, and a preparation material of the black matrices is graphite.

5. The OLED display panel of claim 1, wherein the OLED display panel further comprises an interlayer insulating layer and a planarization layer, and the thermal conduction functional layer is disposed between the interlayer insulating layer and the planarization layer.

6. The OLED display panel of claim 5, wherein the thermal conduction functional layer is disposed on an entire surface between the interlayer insulating layer and the planarization layer.

7. The OLED display panel of claim 5, wherein a recessed area is disposed on an upper surface of the interlayer insulating layer, and the thermal conduction functional layer is disposed in the recessed area.

8. The OLED display panel of claim 7, wherein a cross-sectional shape of the recessed area is any one of a rectangle, a trapezoid, a triangle, a rhombus, or a parallelogram.

9. The OLED display panel of claim 4, wherein the thermal conduction functional layer is disposed between the black matrices and the encapsulation layer.

10. The OLED display panel of claim 9, wherein an orthographic projection of the thermal conduction functional layer on the substrate coincides or overlaps an orthographic projection of the black matrices on the substrate.

11. The OLED display panel of claim 4, wherein the thermal conduction functional layer is disposed between the color resist blocks and the encapsulation layer.

12. The OLED display panel of claim 4, wherein the color filter further comprises a cover plate disposed above the black matrices, and the thermal conduction functional layer is disposed between the cover plate and the black matrices and the color resist blocks.

13. The OLED display panel of claim 4, wherein the thermal conduction functional layer is disposed on both upper surfaces and lower surfaces of the black matrices and color resist blocks.

14. The OLED display panel of claim 4, wherein a cover plate is disposed above the black matrices, and an optical adhesive is disposed on a surface of the black matrices facing the cover plate.

15. The OLED display panel of claim 14, wherein the black matrices are defined with grooves, and the optical adhesive is partially filled in the grooves.

16. The OLED display panel of claim 1, wherein the thermal conduction functional layer is an insulating material, and the thermal conduction functional layer is disposed between any adjacent film layers.

17. The OLED display panel of claim 1, wherein the thermal conduction functional layer is a conductive material, and the thermal conduction functional layer is disposed between any adjacent insulating layers.

18. The OLED display panel of claim 1, wherein the OLED display panel further comprises an isolation layer, the isolation layer is an insulating material, and the isolation layer is disposed on at least one surface of the thermal conduction functional layer.

19. The OLED display panel of claim 18, wherein the isolation layer is disposed around the thermal conduction functional layer.

20. The OLED display panel of claim 1, wherein the thermal conduction functional layer is one or more of a buffer layer, an interlayer insulating layer, a planarization layer, and the encapsulation layer.
